(19) United States
(12) Patent Application Publication
(10) Pub. No.: US 2026/0255932 A1
(43) Pub. Date: Aug. 27, 2026

(54) MANUFACTURE METHOD FOR MANUFACTURING A WAFER STRUCTURE

(71) Applicant: Okmetic Oy, Vantaa (FI)

(72) Inventor: Katja PARKKINEN, Vantaa (FI)

(21) Appl. No.: 18/987,134

(22) Filed: Dec. 19, 2024

(51) Int. Cl. H10P 90/00; H10D 86/00; H10W 10/10

(52) U.S. Cl. CPC H10P 90/1906; H10D 86/201; H10W 10/181

(57) ABSTRACT

The application relates to a manufacture method (100) for manufacturing a wafer structure (238, 248). The manufacture method comprises a following step of establishing (102) a top wafer (204). The manufacture method further comprises a following step of depositing (112) a trap-rich layer (214) on the top wafer. The manufacture method further comprises a following step of bonding (122) a handle wafer (224) on the top wafer so that the trap-rich layer is between the top and handle wafers (204, 224) to produce the wafer structure. The wafer structure comprises the trap-rich layer bonded against the handle wafer so that a grain structure in the trap-rich layer is coarser adjacent to the handle wafer and a grain size in the grain structure decreases away from the handle wafer to improve a trapping efficiency of the wafer structure in the trap-rich layer in an interface (IF) towards the top wafer.

### TECHNICAL FIELD

The application relates generally to a manufacture method for manufacturing a wafer structure.

### BACKGROUND

High resistivity silicon (HRS) wafers are special semiconductor substrates with resistivity values typically above 1000 Ohm-cm. This high resistivity reduces the number of free carriers in the material, which minimizes conductive losses and interference that can affect signal quality. These properties make the HRS wafers suitable for radio frequency (RF) devices, wherein it is essential to maintain signal integrity, reduce noise, and ensure efficient transmission. The HRS wafers thus improve the performance and reliability of RF circuits.

The HRS wafers are further improved for RF devices by depositing a trap-rich layer on the surface of the HRS wafers. The trap-rich layer captures and traps free charges on the surface. This charge trapping capability prevents a formation of parasitic conduction paths, which can degrade signal quality. The trap-rich layer helps to stabilize the electrical properties of the HRS wafers by reducing interference in the RF circuits and improving isolation, which is crucial for high-performance RF devices.

HRS wafers with the trap-rich layer are used in different kind of RF devices, e.g., integrated passive devices (IPDs), filters, resonators, power amplifiers, and RF switches. These RF devices are critical for efficient signal processing and transmission in wireless communication systems. Inductors, filters, and resonators, e.g., benefit from the High-quality factor (Q) of the HRS wafers, which helps to reduce energy losses and allows for precise signal filtering. Inductors and power amplifiers also perform better on HRS wafers with a trap-rich layer as the reduced interference increases efficiency.

One known wafer structure for the RF devices is a so-called oxidized engineered high-resistivity structure (EHRS), which comprises a silicon wafer as a handle wafer, a silicon dioxide layer as an insulation layer on the silicon wafer, and a buried polysilicon layer as a trap-rich layer between the silicon wafer and the silcon dioxide layer. The oxidized EHRS is manufactured by depositing the thin polysilicon layer, which is 100 nm-several µm thick, on the silicon wafer and then oxidizing the silicon wafer to obtain the silicon dioxide layer on the polysilicon layer so that the desired EHRS structure is completed, when the trap-rich layer is between the handle wafer and the insulation layer.

### SUMMARY

One object of the invention is to withdraw the drawbacks of known solutions and to provide a wafer structure for radio frequency (RF) devices, which comprises a thicker, inverted grain structure of a trap-rich layer by enabling an improved (enhanced) charge trapping capability and suppression of parasitic surface conductivity in the wafer structure.

The inverted grain structure also enables an improved (enhanced) RF performance (properties) in typical operation temperature range, a decreased thermal dependency of the the RF performance, and a higher process temperature in subsequent steps without compromising the RF performance.

One object of the invention is fulfilled by providing a manufacture method and wafer structure according to the independent claims.

Embodiments of the invention are disclosed in the claims.

One manufacture method for manufacturing a wafer structure comprises a following step of establishing a top wafer. The manufacture method further comprises a following step of depositing a trap-rich layer on the top wafer. The manufacture method further comprises a following step of bonding a handle wafer on the top wafer so that the trap-rich layer is between the top and handle wafers to produce the wafer structure. The wafer structure comprises the trap-rich layer bonded against the handle wafer so that a grain structure in the trap-rich layer is coarser adjacent to the handle wafer and a grain size in the grain structure decreases away from the handle wafer to improve a trapping efficiency of the wafer structure in the trap-rich layer in an interface towards the top wafer.

One wafer structure for a RF device, which is manufactured by the previous manufacturing method comprises a trap-rich layer and a handle wafer. The trap-rich layer is on the handle wafer. The trap-rich layer is bonded against the handle wafer so that a grain structure in the trap-rich layer is coarser adjacent to the handle wafer and a grain size in the grain structure decreases away from the handle wafer to improve a trapping efficiency of the wafer structure in the trap-rich layer in an interface towards the top wafer.

One wafer structure for a RF device, which is manufactured by the previous manufacturing method comprises an insulation layer, a trap-rich layer, and a handle wafer. The trap-rich layer is on the insulation layer so that the trap-rich layer is between the insulation layer and the handle wafer. The trap-rich layer is bonded against the handle wafer so that a grain structure in the trap-rich layer is coarser adjacent to the handle wafer than adjacent to the insulation layer and a grain size in the grain structure decreases away from the handle wafer to improve a trapping efficiency of the wafer structure in the trap-rich layer in the interface of the trap-rich and insulation layers.

### BRIEF DESCRIPTION OF THE FIGURES

The exemplary embodiments of the invention are explained with reference to the accompanying figures:

FIG. 1 presents a flowchart of a manufacture method of a wafer structure

FIG. 2a presents a resulted wafer structure for each step of the manufacture method, when an insulation layer is produced on a top layer

FIG. 2b presents a resulted wafer structure for each step of the manufacture method without the insulation layer

### DETAILED DESCRIPTION OF THE FIGURES

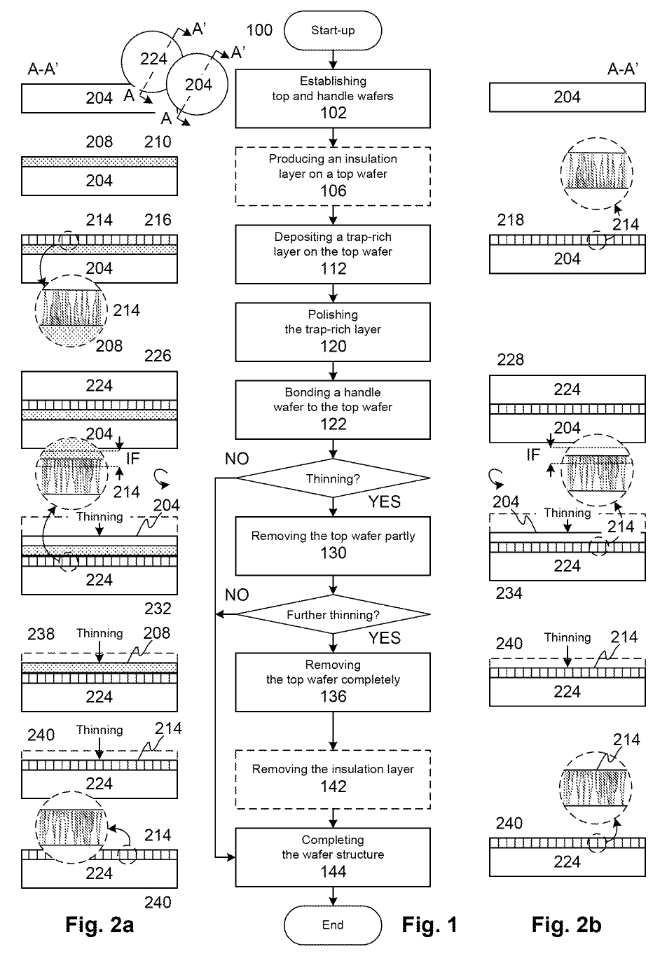

FIG. 1, 2a, and 2b present a manufacture method 100 to manufacture a wafer structure 232, 234, 238, 240, which is a suitable substrate (platform) for a radio frequency (RF) device (not presented), and a resulted structure for each of manufacture steps 210, 216, 218, 226, 228, 232, 234, 238, 240.

The RF device, which can be manufactured (integrated) on the wafer structure 238, 240 comprises, e.g., surface acoustic wave filters (SAWs), bulk acoustic wave filters (BAWs), film bulk acoustic wave resonators (FBARs), integrated passive devices (IPDs), and other types of RF devices that can be integrated on the wafer structure 238, 240.

At a step 102, top (device) and handle (substrate) wafers 204, 224 are established. The top wafer 204 comprises a semiconductor top wafer or a piezo top wafer. The semiconductor top wafer 204 comprises a silicon (Si), e.g., a standard or high resistivity silicon, silicon-germanium (SiGe), or silicon carbide (SiC) wafer. The piezo top wafer 204 comprises a lithium niobate (LiNbO₃) or lithium tantalate (LiTaO₃) wafer.

At a step 106, if the wafer structure 232, 238, 240 comprises an insulation layer 208, the insulation layer 208 is produced on the top wafer 204 to obtain (accomplish) a wafer structure 210, which comprises the insulation layer 208 above the top wafer 204.

The insulation layer 208 comprises thermal silicon dioxide (SiO₂), deposited silicon dioxide, deposited silicon nitride (Si₃N₄), deposited silicon oxynitride (Si₂N₂O), deposited aluminum oxide (Al₂O₃), deposited hafnium oxide (HfO₂), deposited titanium oxide (TiO₂), deposited zirconium oxide (ZrO₂), deposited lanthanum oxide (La₂O₃), deposited barium oxide (BaO), or deposited aluminum nitride (AlN) layer 208.

At a step 112, irrespective of whether the insulation layer 208 exists on the top wafer 204 or not, a trap-rich layer 214 is deposited on the top wafer 204 to establish the trap-rich layer 214 into an interface IF of the trap-rich layer 214 and the below structure.

The trap-rich layer 214 is deposited by a chemical vapour deposition (CVD) to accomplish a wafer structure 216, which comprises the trap-rich layer 214 above the wafer structure 210, i.e., above the insulation layer 208, after the production of the insulation layer 208 or a wafer structure 218, which comprises the trap-rich layer 214 directly above the top wafer 204 after the establishment of the top wafer 204, when the wafer structure 218 lacks an insulation layer. The trap-rich layer 214 is alternatively deposited by sputtering to accomplish the wafer structure 216 or the wafer structure 218.

The trap-rich layer 214, which comprises a polycrystalline trap-rich layer, which comprises polysilicon (PSi), silicon carbide, aluminium nitride, germanium (Ge), or silicon-germanium, has a deposition (growth) morphology in which a growth of the trap-rich layer 214 starts with fine (small) grains and continues with a columnar structure and larger (bigger) grains as a grain size increases.

The trap-rich layer 214 thus comprises a grain structure that is finer adjacent to the below structure, i.e., the insulation layer 208 or the top wafer 204, than an upper surface of the trap-rich layer 214. The grain size in the grain structure increases away from the insulation layer 208 or the top wafer 204 because of the deposition morphology of the trap-rich layer 214, when the growth of the trap-rich layer 214 starts with the fine grains and then continues with the larger grains in a columnar fashion towards the upper surface of the trap-rich layer 214 according to the figures.

At the step 112, if the trap-rich layer 214 is amended after its deposition, the wafer structure 216, 218 is processed by high temperature processing, e.g., rapid thermal annealing, at temperature above 800°C to amend the grain size of the structure or the interface IF of the trap-rich layer 214 and to stabilize the grain structure in the trap-rich layer 214 so that a charge trapping capability of the trap-rich layer 214 improves, which prevents more efficiently a formation of parasitic conduction paths and a degradation of signal quality in the RF devices.

At a step 120, the trap-rich layer 214, i.e., the upper surface of the trap-rich layer 214, is polished before the bonding of the wafer structure 216, 218 and the handle wafer 224.

At a step 122, the handle wafer 224 is bonded by direct bonding, e.g., by fusion bonding, e.g., plasma activated fusion bonding, by hybrid bonding, by anodic bonding, or by conductive bonding, on the wafer structure 216, 218 so that the trap-rich layer 214 is between the top and handle wafers 204, 224 to accomplish a wafer structure 226, which comprises the insulation layer 208, or a wafer structure 228, which lacks the insulation layer.

The handle wafer 224 comprises a semiconductor handle wafer, which comprises silicon, e.g., a standard or high resistivity silicon, silicon carbide, or indium phosphide (InP), or an insulation handle wafer, which comprises glass, sapphire, or quartz.

The wafer structure 226, 228 comprises the trap-rich layer 214 bonded against the handle wafer 224 so that the grain structure in the trap-rich layer 214 is coarser adjacent to the handle wafer 224 than adjacent to the insulation layer 214, when the insulation layer 214 exists in the wafer structure 216, or the top wafer 204, when the wafer structure 218 lacks the wafer structure. The grain size in the grain structure decreases away from the handle wafer 224 to improve a trapping efficiency of the wafer structure 226, 228 in the trap-rich layer 214 in the interface IF towards the top wafer 204, when smaller grains sizes cause the better trapping efficiency than larger grain sizes.

At a step 130, the wafer structure 226, 228 is thinned by etching, by grinding, by polishing, or by a combination of at least two of the previous thinning methods to remove the top wafer 204 partly on the trap-rich layer 214 to accomplish a wafer structure 232 corresponding with a so-called trap-rich silicon-on-insulator (TR-SOI) structure, which comprises the insulator layer 208, or a wafer structure 234, which lacks the insulator layer, so that the accomplished wafer structures 232, 234 comprises the buried trap-rich layer 214 between the top and handle wafers 204, 224.

At a step 136, the wafer structure 232, 234 is further thinned by etching, by grinding, by polishing, or by a combination of at least two of the previous thinning methods the top wafer 204 completely on the trap-rich layer 214 to accomplish a wafer structure 238 corresponding with a so-called oxidized engineered high-resistive structure (oxidized EHRS), which comprises the insulator layer 208, or a wafer structure 240 corresponding with a so-called engineered high-resistive structure (EHRS), which lacks the insulator layer.

At a step 142, if the wafer structure 238 still comprises the insulation layer 208 and it is necessary to remove it, the wafer structure 238 is thinned by etching, by grinding, by polishing, or by a combination of at least two of the previous thinning methods to remove the insulation layer 214 completely on the trap-rich layer 214 to accomplish the wafer structure 240, i.e., the engineered high-resistive structure, which lacks the insulator layer 208.

At a step 144, when the desired wafer structure 232, 234, 238, 240 has been accomplished and further thinning is unnecessary, the wafer structure 232, 234, 238, 240 is completed by sorting, cleaning, inspecting, and packing the wafer structures 232, 234, which comprise the thinned top wafer 204 above the insulator layer 208 or the trap-rich layer 214, the wafer structure 238, which comprises the insulator layer 208 above the trap-rich layer 214, or the wafer structures 240, which comprise only the trap-rich layer 214 above the handle wafer 224.

The invention has been now explained above with reference to the exemplary embodiments and its several advantages have been demonstrated. It is clear that the invention is not only restricted to these embodiments, but it comprises all possible embodiments within the scope of the following claims.

1. A manufacture method (100) for manufacturing a wafer structure (238, 240), comprising at least following steps of
establishing (102) a top wafer (204),
depositing (112) a trap-rich layer (214) on the top wafer, and
bonding (122) a handle wafer on the top wafer so that the trap-rich layer is between the top and handle wafers (204, 224) to produce the wafer structure,
wherein the wafer structure comprises the trap-rich layer bonded against the handle wafer so that a grain structure in the trap-rich layer is coarser adjacent to the handle wafer and a grain size in the grain structure decreases away from the handle wafer to improve a trapping efficiency of the wafer structure in the trap-rich layer in an interface (TR) towards the top wafer.

2. The manufacture method according to the previous claim, which further comprises a step of producing (106) an insulation layer (208) on the top wafer before the deposition of the trap-rich layer on the insulation layer to establish the trap-rich layer into an interface (IF) of the trap-rich and insulation layers (208, 214).

3. The manufacture method according to claim 2, wherein the insulation layer comprises a thermal silicon dioxide, a deposited silicon dioxide, a deposited silicon nitride, or a deposited silicon oxynitride.

4. The manufacture method according to any of claims 2 - 3, wherein the grain structure of the trap-rich layer is coarser adjacent to the silicon handle wafer than adjacent to the insulation layer to improve the trapping efficiency of the wafer structure in the trap-rich layer in the interface (IF) of the trap-rich and insulation layers (208, 214).

5. The manufacture method according to any of claims 2 - 4, which further comprises a step of thinning (136) the insulation layer to remove the insulation layer completely on the trap-rich layer.

6. The manufacture method according to any of the previous claims, wherein the trap-rich layer is deposited on the top wafer by a chemical vapour deposition.

7. The manufacture method according to any of the previous claims, wherein the trap-rich layer comprises a polycrystalline trap-rich layer (214).

8. The manufacture method according to claim 7, wherein the polycrystalline trap-rich layer comprises polysilicon, silicon carbide, or aluminium nitride.

9. The manufacture method according to any of the previous claims, wherein the trap-rich layer is annealed by rapid thermal annealing to stabilize the grain structure in the trap-rich layer to improve a charge trapping capability of the trap-rich layer.

10. The manufacture method according to any of the previous claims, which further comprises a step of polishing (120) the trap-rich layer before the bonding of the top and handle wafers.

11. The manufacture method according to any of the previous claims, which further comprises a step of thinning (130, 136) the wafer structure to remove the top wafer completely on the trap-rich layer to obtain the wafer structure.

12. The manufacture method according to any of the previous claims, wherein the top wafer comprises a semiconductor top wafer (204), which comprises silicon.

13. The manufacture method according to any of the previous claims, wherein the handle wafer comprises a semiconductor handle wafer (224), which comprises silicon, silicon carbide, or indium phosphide, or an insulation handle wafer (224), which comprises glass, sapphire, or quartz.

14. A wafer structure (240) for a radio frequency device, which is manufactured by the manufacturing method (100) according to any of the previous claims, comprising
a trap-rich layer (214) and
a handle wafer (224),
which trap-rich layer is on the handle wafer,
wherein the trap-rich layer is bonded against the handle wafer so that a grain structure in the trap-rich layer is coarser adjacent to the handle wafer and a grain size in the grain structure decreases away from the handle wafer to improve a trapping efficiency of the wafer structure in the trap-rich layer in an interface (IF) towards the top wafer.

15. A wafer structure (238) for a radio frequency device, which is manufactured by the manufacturing method (100) according to any of claims 1 - 13, comprising
an isulation layer (208),
a trap-rich layer (214), and
a handle wafer (224),
which trap-rich layer is on the insulation layer so that the trap-rich layer is between the insulation layer and the handle wafer,
wherein the trap-rich layer is bonded against the handle wafer so that a grain structure in the trap-rich layer is coarser adjacent to the handle wafer than adjacent to the insulation layer and a grain size in the grain structure decreases away from the handle wafer to improve a trapping efficiency of the wafer structure in the trap-rich layer in the interface (IF) of the trap-rich and insulation layers (208, 214).
